(19) United States
(12) Patent Application Publication
(10) Pub. No.: US 2009/0150730 A1
(43) Pub. Date: Jun. 11, 2009

(54) Test apparatus for data storage device and test method for data storage device

(76) Inventors: Nubuo Takeda, Kanagawa (JP); Masaki Kuwashima, Kanagawa (JP); Satoshi Takahashi, Kanagawa (JP); Masashi Tsuyama, Kanagawa (JP)

Correspondence Address: TOWNSEND AND TOWNSEND AND CREW LLP, TWO EMBARCADERO CENTER, 8TH FLOOR, SAN FRANCISCO, CA, 94111, US

(21) Appl. No.: 12/291,861

(22) Filed: Nov. 14, 2008

(30) Foreign Application Priority Data
Dec. 7, 2007 (JP) 2007-317759

(51) Int. Cl. G11C 29/00

(52) U.S. Cl. 714/721

(57) ABSTRACT

In a test apparatus for a data storage device, embodiments of the present invention help to support data storage devices with different specifications using a single processor. According to one embodiment, a test apparatus comprises a processor card and adapter cards. The adapter cards comprise power supply circuits to generate power supply voltages to be supplied to the hard disk drives (HDDs). Implementing power supply circuits in the adapter card accomplishes flexible support for HDDs with various specifications with a single processor cards. Since a plurality of HDDs are concurrently tested with a single processor card, it is not necessary to mount a plurality of power supply circuits on the processor card so that the processor card can be decreased in size.

### CROSS-REFERENCE TO RELATED APPLICATION

The instant nonprovisional patent application claims priority to Japanese Patent Application No. 2007-317759 filed Dec. 7, 2007 and which is incorporated by reference in its entirety herein for all purposes.

### BACKGROUND OF THE INVENTION

Data storage devices equipped with a memory for storing data, such as a semiconductor memory, a magnetic memory, an optical memory, or the like, have been known in the art. In particular, hard disk drives (HDDs) have been widely used as storage devices of computers and have been one of indispensable external storage devices for current computer systems. Moreover, the HDDs have found widespread application to moving image recording/reproducing apparatuses, car navigation systems, cellular phones, and the like, in addition to the computers, due to their outstanding characteristics.

A magnetic disk used in an HDD has multiple concentric data tracks and servo tracks. Each data track includes multiple data sectors containing user data recorded thereon. Each servo track contains address information. A servo track is constituted by a plurality of servo data arranged discretely in the circumferential direction. One or more data sectors are recorded between servo data. A head slider accesses a desired data sector in accordance with address information in servo data to write data to and retrieve data from the data sector.

In manufacturing HDDs, an operational test, and setting and adjustment of parameters are performed on the HDDs connected to a test computer (for example, refer to Japanese Patent Publication No. 2004-342304 “Patent Document”). A chamber to be used in the test of HDDs comprises a number of cells (rooms) and HDDs are disposed in the cells. In each cell, an HDD is connected to a processor card of a test computer in circuitry; the processor card tests the HDD.

FIG. 7 is a block diagram schematically illustrating a partial configuration of a test apparatus for an HDD and an HDD connected to the test apparatus according to a related art. A program for the test of an HDD 71 is downloaded to a processor card 72 from an external computer and the processor card 72 conducts a test of the HDD 71. The processor card 72 comprises a substrate 721, a processor 722 mounted on the substrate, a RAM 725, and two power supply logics 723 and 724 for generating power supply voltages to be supplied to the HDD 71.

The processor card 72 is connected to an interface card 73. The interface card 73 comprises a substrate 731, and an interface controller 732 is mounted on the substrate 731. The interface controller 732 executes interface processes between the HDD 71 and the processor 722. An adapter card 74 is located between the interface card 73 and the HDD 71, and is connected to both of them. The adapter card 74 comprises a substrate 741 with only wirings and passive circuits (not shown) arranged thereon. The adapter card 74 functions as a connector converter.

HDDs 71 require different power supply voltages depending on their size. A 3.5-inch HDD requires power supply voltages of 12 V and 5 V; a 2.5-inch HDD requires a power supply voltage of 5 V. An HDD 5-V logic 723 and an HDD 12-V logic 724 in the processor card 72 generate power supply voltages of 5 V and 12 V, respectively. They supply the power supply voltage to the HDD 71 under control of the processor 722. The power supply voltages generated by the two power supply circuits 723 and 724 are supplied to the HDD 71 through the interface card 73 and the adapter card 74. The interface card 73 and the adapter card 74 transfer test signals including commands and data between the processor 722 and the HDD 71.

In the operating environment of the HDD 71, the power supply voltage is not constant but varies. Accordingly, in the test of the HDD 71, there is a test which varies the power supply voltage to the HDD 71 within a specific range and ascertains whether or not the HDD 71 normally operates in the varying power supply voltage. For an efficient test of the HDD 71, it is preferable to be able to control the power supply voltage for each HDD 71. To that end, it is necessary to prepare a power supply circuit for every HDD 71.

Improvement in a multitask function and performance of the processor 722 has enabled a single processor 722 to test a plurality of HDDs 71 concurrently. However, in the above conventional test apparatus for HDDs, power supply circuits 723 and 724 to supply necessary power for the HDD 71 are implemented in the processor card 72. Since the processor card 72 is disposed in a limited room in the chamber, the size of the substrate is obviously limited. Besides, since the power supply circuit has a certain size, the number of power supply circuits capable of being mounted on the processor card 72 is limited. Therefore, in order to prepare a power supply circuit for each HDD 71, it is necessary to prepare a processor card 72 for each HDD 71; one processor card 72 is required for one HDD 71.

The HDDs 71 have different required power supply voltages and source capacities depending on the specification. In the above-described conventional HDD test apparatus, if power supply conditions required for the HDD 71 have been changed, it is necessary to change the processor card 72 for the conditions. It is desired that a single processor card 72 can support tests for HDDs 71 with different specifications in a test apparatus for HDDs.

### BRIEF SUMMARY OF THE INVENTION

In a test apparatus for a data storage device, embodiments of the present invention help to support data storage devices with different specifications using a single processor. In the specific embodiment of FIG. 5, a test apparatus of comprises a processor card 6 and adapter cards 3a and 3b. The adapter cards 3a and 3b comprise power supply circuits 33a, 33b, 34a, and 34b to generate power supply voltages to be supplied to HDDs 1a and 1b. Implementing power supply circuits in the adapter card accomplishes flexible support for HDDs with various specifications with a single processor cards. Since a plurality of HDDs are concurrently tested with a single processor card, it is not necessary to mount a plurality of power supply circuits on the processor card, so the processor card can be decreased in size.

### BRIEF DESCRIPTION OF THE DRAWINGS

FIG. 1 is a plan view schematically depicting an internal configuration of an HDD of a test subject device according to an embodiment.

FIG. 2 is a perspective view schematically depicting a chamber of a test apparatus according to an embodiment.

FIG. 3 is a perspective view schematically depicting the configuration of a part of the chamber surrounded by dotted line A in FIG. 2 in an embodiment.

FIG. 4 is a cross-sectional view schematically illustrating devices disposed in cells of the chamber in an embodiment.

FIG. 5 is a block diagram schematically illustrating the circuit configuration of HDDs, adapter cards, an interface card, and a processor card in an embodiment.

FIG. 6 is a block diagram schematically illustrating the circuit configuration of the adapter card according to an embodiment.

FIG. 7 is a block diagram schematically illustrating the circuit configuration of a test apparatus for an HDD in a conventional technique.

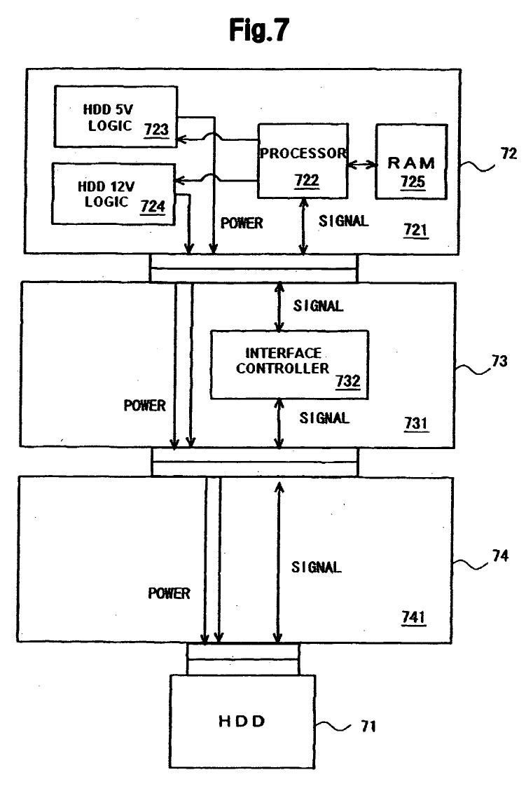

### DETAILED DESCRIPTION OF THE INVENTION

Embodiments of the present invention relate to a test apparatus and a test method for a data storage device, and more particularly to a power supply to a data storage device in a test of the data storage device.

An embodiment of a test apparatus for a data storage device according to an aspect of the present invention comprises a chamber including a room for housing a data storage device of a test subject, a processor card including a processor for testing the data storage device and a first substrate where the processor is mounted, and an adapter card including a second substrate located between the processor card and the data storage device for transmitting test signals between the processor card and the data storage device and a power supply circuit mounted on the second substrate for supplying an operational power supply voltage for the data storage device. The power supply circuit mounted on the adapter allows a single processor to support data storage devices with different specifications.

A connector may be fixed to the second substrate of the adapter card, and the connector can be connected directly to a connector of the data storage device. Further, the adapter card may include a power supply control circuit for controlling the power supply circuit. This accomplishes an efficient connection of the data storage device and the adapter card.

The test apparatus may comprise an interface card including a third substrate located between the processor card and the adapter card for transmitting test signals between the processor card and the data storage device and an interface controller mounted on the third substrate for performing interface processes between the processor card and the data storage device. This allows a single processor to support data storage devices with different specifications.

A plurality of adapter cards may be connected to the processor card, and the processor card tests a plurality of data storage devices connected to the plurality of adapter cards concurrently. This accomplishes an efficient test. Moreover, the processor card can control power supply circuits on the plurality of adapter cards individually. This accomplishes a flexible and efficient test.

The test apparatus may comprise an interface card including a fourth substrate located between the processor card and the plurality of adapter cards for transmitting test signals between the processor cards and the plurality of data storage devices and an interface controller mounted on the fourth substrate for performing interface processes between the processor card and the plurality of data storage devices. This accomplishes an efficient test. The interface card may be connected to each of the plurality of adapter cards via a signal transmission cable. This accomplishes wide selection of sizes and arrangements of the cards.

Another aspect of embodiments of the present invention is a test method for a plurality of data storage devices. This method prepares a processor card including a first substrate and a processor mounted on the first substrate. It connects the plurality of data storage devices to substrates of a plurality of adapter cards for transmitting test signals between the processor card and the plurality of data storage devices. It supplies operational power supply voltages different in each of the plurality of data storage devices by power supply circuits mounted on the adapter cards. It tests the plurality of data storage devices operating at different operational power voltages by the processor. This method accomplishes an efficient and flexible test on a plurality of data storage device.

The method can perform interface processes of test signals between the processor and the plurality of data storage devices by a single interface controller. This accomplishes a more efficient test on a plurality of data storage devices. Also, each connector of the plurality of data storage devices may be connected directly to each connector of the plurality of adapter cards. This allows the adapter card to be efficiently connected to the data storage device.

According to embodiments of the present invention, a processor can support data storage devices with different specifications in a test apparatus for data storage devices.

Hereinafter, particular embodiments of the present invention will be described. For clarity of explanation, the following description and the accompanying drawings contain omissions and simplifications as appropriate. Throughout the drawings, like components are denoted by like reference numerals, and their repetitive description is omitted if not necessary for clarity of explanation. In the particular embodiments, descriptions will be given to a hard disk drive (HDD) as an example of a test subject data storage device. A feature of the test apparatus for data storage devices according to embodiments is the circuit configuration therein.

The test apparatus of one embodiment comprises a processor card with a processor mounted on its substrate and an adapter card to support various HDDs with different specifications. The adapter card is located between the processor card and an HDD in the circuit configuration and is connected to the HDD. The adapter card of the present embodiment further comprises a power supply circuit to generate a power supply voltage to be supplied to the HDD. In the present specification, the adapter card is a card which is located between an HDD and a processor card in circuitry and includes circuit components to meet the specification of the HDD.

A power supply circuit implemented in the adapter card allows preparing an appropriate power supply circuit for each HDD so that merely replacing the adapter card allows tests of HDDs with various power supply specifications. As a result, since a single processor card can support tests of HDDs with various power supply specifications, it is not necessary to implement a plurality of power supply circuits in the processor card and it is available to flexibly support HDDs with various specifications Besides, implementing a power supply circuit in the adapter card eliminates the necessity of implementing a plurality of power supply circuits in the processor card in order to test a plurality of HDDs concurrently using a single processor card, so that the processor card can be decreased in size.

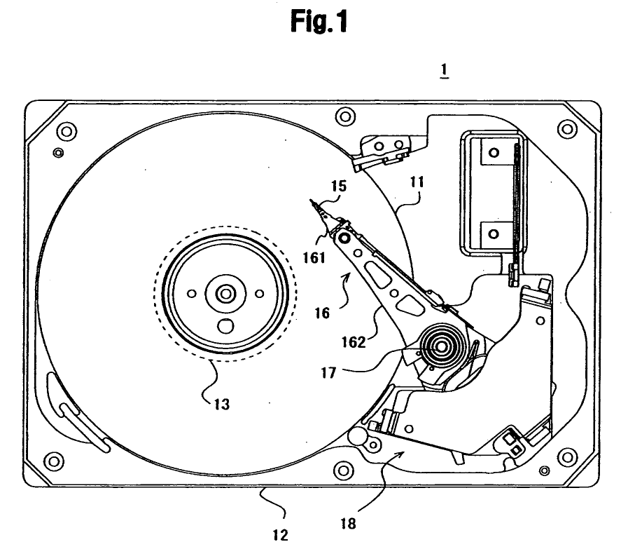

First, the configuration of an HDD to be tested by the test apparatus of an embodiment will be described referring to FIG. 1. An HDD 1 comprises a magnetic disk 11 which is a non-volatile memory to record data by magnetizing a magnetic layer. A base 12 houses components of the HDD 1. The base 12 is fixed to a cover (not shown) for closing its top opening with a gasket (not shown) interposed therebetween to constitute an enclosure. A head slider 15 comprises a head element portion for writing to and/or reading from the magnetic disk 11 with regard to data input from and/or output to a host (not shown) and a slider a surface on which the head element portion is formed. The head element portion includes a recording element for converting electric signals to magnetic fields and/or a reproducing element for converting magnetic fields from the magnetic disk 11 to electric signals.

An actuator 16 comprises a suspension 161 for supporting a head slider 15 and an arm 162 to which the suspension 161 is fixed. The actuator 16 swings about a shaft 17 and is driven by a voice coil motor 18. A spindle motor (SPM) 13 fixed to the base 12 spins the magnetic disk 11 at a specific speed. The actuator 16 moves the head slider 15 over a data area on the spinning magnetic disk 11 for retrieving data from/writing data to the magnetic disk 11. The pressure by air viscosity between the air bearing surface (ABS) of the slider and the spinning magnetic disk 11 balances the pressure applied toward the magnetic disk 11 by the suspension 161 for the head slider 15 to fly above the magnetic disk 11 with a certain gap. The operational control of the HDD 1 is performed by a control circuit (not shown) mounted on a substrate fixed outside the base 12.

Typical manufacturing of an HDD 1 first manufactures a head slider 15. Aside from the head slider 15, it manufactures a suspension 161. It bonds the head slider 15 to the suspension 161 to manufacture a head gimbal assembly (HGA). Then, it fixes an arm 162 and a VCM coil to the HGA to manufacture a head stack assembly (HSA) which is an assembly of the actuator 16 and the head slider 15. It mounts an SPM 13, a magnetic disk 11, and the like in addition to the manufactured HSA within a base 12 and closes the space inside the base 12 with a top cover to complete a head disk assembly (HDA). It mounts a circuit board (not shown) with control circuits mounted thereon on the HDA to finish the HDD 1.

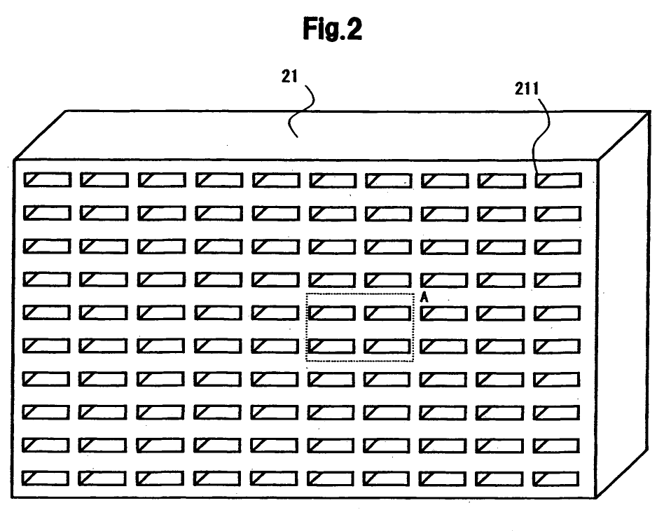

The HDD 1 assembled in this way is transferred to a test step in manufacturing. The HDD 1 is placed within a partitioned room in a chamber constituting a test apparatus and is connected to a processor card of a test computer. The test for the HDD 1 conducts a plurality of tests, such as setting parameters, an operational test, and a defect detection test of the magnetic disk 11. FIG. 2 is a perspective view schematically depicting a chamber 21 of the test apparatus. The chamber 21 comprises a plurality of partitioned rooms (cells) 211; each cell 211 houses an HDD 1. Typically, a plurality of HDDs 1 are disposed in a cell 211. Although not shown in the drawing, a typical chamber 21 comprises a large door for closing all the cells 211 or doors for individual cells 211; the doors are closed in the test of HDDs 1.

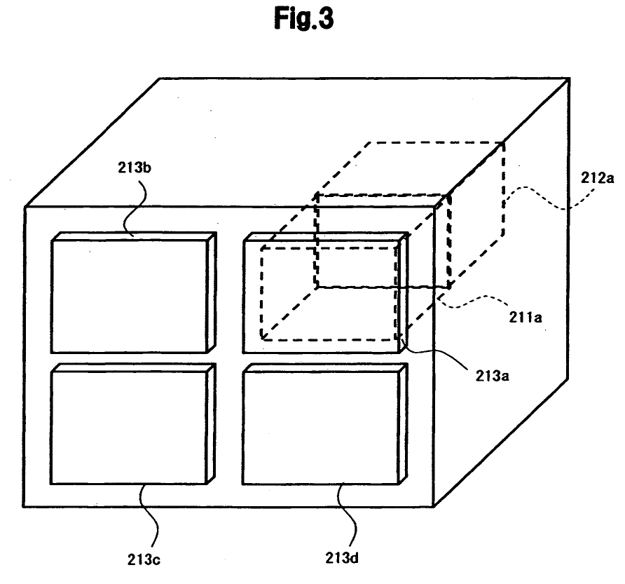

FIG. 3 is a perspective view schematically depicting the configuration of a part of the chamber 21 surrounded by dotted line A in FIG. 2. FIG. 3 shows four cells of the chamber 21; the inside of one cell 211a of the four and a cell 212a behind it are indicated in dotted lines. An HDD 1 is placed in the cell 211a. Doors 213a to 213d are provided on the front of the four cells; they are opened when the HDD 1 is put in and put out of the cell and are closed during a test. In the cell 212a behind the cell 211a for housing the HDD 1, a processor card for testing the HDD 1 is placed.

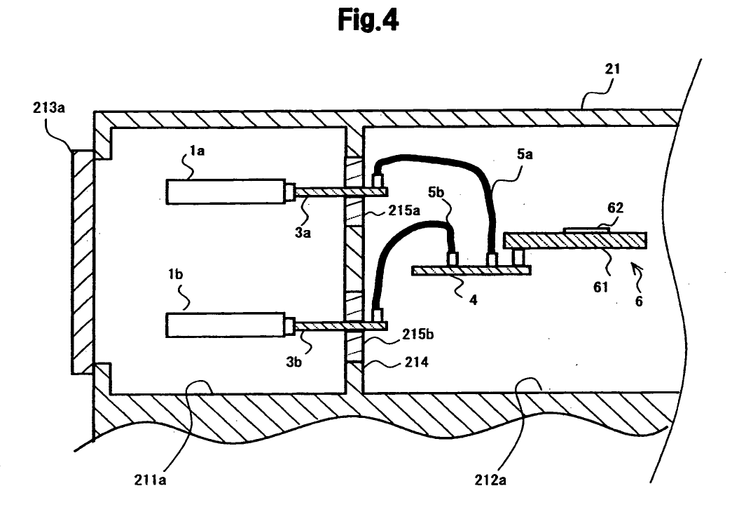

The cross-sectional view of FIG. 4 schematically illustrates a cell 211a, a cell 212a behind the cell 211a, and devices disposed in these cells. The cell 211a houses two HDDs 1a and 1b. The HDDs 1a and 1b are physically connected to adapter cards 3a and 3b, respectively. The adapter cards 3a and 3b penetrate holes provided in a wall 214 separating the cell 211a from the cell 212a; parts of them are exposed in the cell 211a and parts of them are exposed in the cell 212a. Specifically, resin members 215a and 251b are filled in the holes in the wall 214 and the adapter cards 3a and 3b penetrate the resin members 215a and 251b, respectively.

The adapter cards 3a and 3b are connected to an interface card 4 in the cell 212a. Signal transmission cables 5a and 5b connect the adapter cards 3a and 3b and the interface card 4, respectively. Although connectors on the substrates of the adapter cards 3a and 3b may be connected directly to connectors on the substrate of the interface card 4, connecting these through the cables 5a and 5b allows arbitrary selection of arrangement of the adapter cards 3a and 3b and the interface card 4 and their sizes. The interface card 4 is connected to a processor card 6 in the cell 212a. On the substrate 61 of the processor card 6, a processor 62 of a processor and a RAM 65 are mounted. The processor 62 operates in multitasking in accordance with a test program to conduct tests on the two HDDs 1a and 1b concurrently.

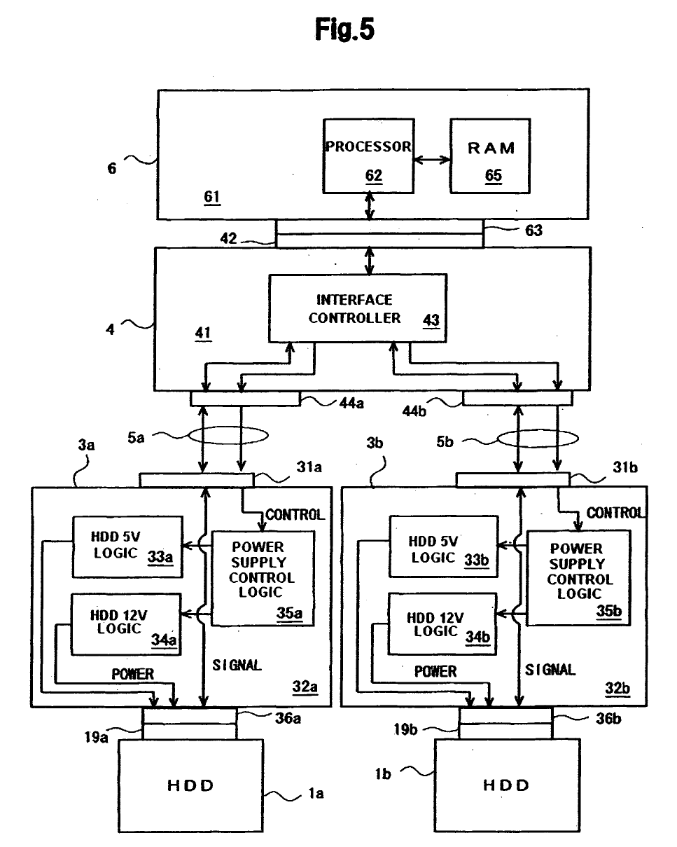

FIG. 5 is a block diagram schematically illustrating a circuit configuration of HDDs 1a and 1b, adapter cards 3a and 3b, an interface card 4, and a processor card 6. A connector 63 is fixed to the substrate 61 of the processor card 6. The connector 63 is connected to a connector 42 fixed to the substrate 41 of the interface card 4. On the substrate 41 of the interface card 4, an interface controller 43 is mounted. Connectors 44a and 44b are fixed to the substrate 41 on the opposite side from the connector 42.

The connector 44a is a connector for connecting to the adapter card 3a, and the connector 44b is a connector for connecting to the adapter card 3b. The connector 44a is connected to a connector 31a of the adapter card 3a via a cable 5a. The connector 44b is connected to a connector 31b of the adapter card 3b via a cable 5b.

The adapter card 3a comprises a logic circuit 33a for generating 5 V of power supply voltage, a logic circuit 34a for generating 12 V of power supply voltage, and a logic circuit 35a for controlling the two power supply circuits 33a and 34a on the substrate 32a of the adapter card 3a. These are the only active circuits possessed by the adapter card 3a; and except for these, only passive circuits such as wirings, connectors, and capacitors are present on the substrate 32a. Similarly, on the substrate 32b of the adapter card 3b, a logic circuit 33b for generating 5 V of power supply voltage, a logic circuit 34b for generating 12 V of power supply voltage, a logic circuit 35b for controlling the two power supply circuits 33b and 34b are mounted. Except for these, only passive circuits such as wirings, connectors, and capacitors are present on the substrate 32b.

On the substrate 32a of the adapter card 3a, a connector 36a for connecting to the HDD 1a is mounted; the connector 36a is connected to a connector 19a of the HDD 1a. In the same manner, the adapter card 3b has a connector 36b for connecting to the HDD 1b, and the connector 36b is connected to a connector 19b of the HDD 1b.

In the configuration of FIG. 5, signals and the power supply voltage between the circuits are transmitted through wirings on the substrates of the HDDs 1a and 1b, the adapter cards 3a and 3b, the interface card 4, and the processor card 6 and connectors interconnecting them. Operation and process of each circuit component will be described specifically. A test program for the HDDs 1a and 1b is downloaded from an external computer to the processor card 6 and is stored in the RAM 65. The processor 62 controls and executes tests on the HDDs 1a and 1b in accordance with the program stored in the RAM 65. The processor 62 performs multitasking to enable concurrent tests on the HDDs 1a and 1b.

The interface controller 43 interfaces test signals including commands and data between the processor 62 and the HDDs 1a and 1b. As an interface for the HDD 1a and 1b, there are a plurality of different types of interfaces such as parallel ATA, serial ATA, SUS, and SCSI. Each type of interface has a different specification in signal transmission speed.

The interface controller 43 is a circuit corresponding to the interface for the HDDs 1a and 1b to be tested among these different interfaces. Typically, another interface controller 43 is used for another interface of the same type but with a different transmission speed. The interface controller 43 has multiple ports to be able to communicate independently with HDDs 1a and 1b connected to the ports.

The interface controller 43 transmits signals for controlling power supply control circuits 35a and 35b in addition to test signals between the processor 62 and the HDDs 1a and 1b. The power supply control circuits 35a and 35b operate in accordance with control signals from the processor 62 transmitted through the interface controller 43. The power supply control circuits 35a ad 35b can control output voltages of the power supply circuits 33a, 34a, 33b, and 34b as well as their ON/OFF.

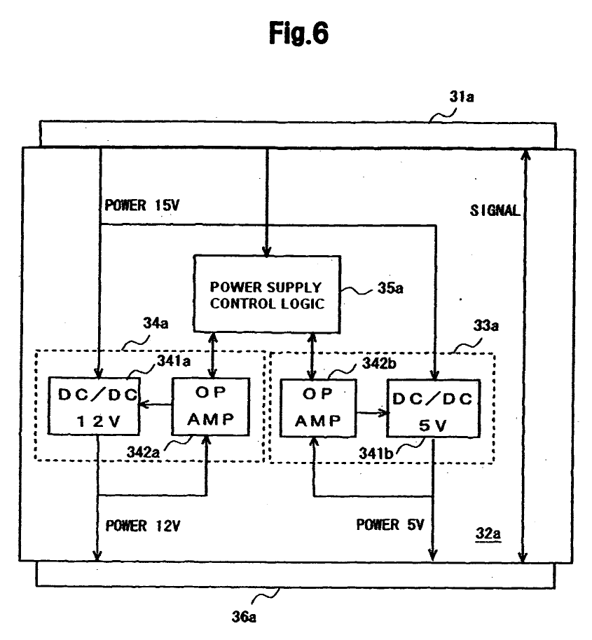

FIG. 6 is a block diagram schematically illustrating a circuit configuration of an adapter card 3a. A 5-V power supply circuit 33a comprises a 5-V DC/DC converter 341b and an operational amplifier 342b. A 12-V power supply circuit 34a comprises a 12-V DC/DC converter 341a and an operational amplifier 342a. The 5-V DC/DC converter 341b and the 12-V DC/DC converter 341a receive 15 V of power supply voltage and can generate 5 V and 12 V of power supply voltages respectively from the power supply voltage. The 15 V of the power supply voltage can be supplied from an external power supply through an interface card 4 and a processor card 6.

The operational amplifiers 342b and 342a configure feed-back circuits and can change the output voltage of the 5-V DC/DC converter 341b and the 12-V DC/DC converter 341a by adjusting the output values of the operational amplifiers 342b and 342a. The power supply control circuit 35a controls the operational amplifiers 342b and 342a under control of the processor 62 to adjust the output voltage of the 5-V power supply circuit 33a and the 12-V power supply circuit 34a. The adapter card 3b has the same configuration as the one of FIG. 6.

The processor 62 can test the HDDs 1a and 1b independently. Generally, the test of the HDDs 1a and 1b includes an operational test under varying power supply voltage. The test apparatus of the present embodiment has independent power supply circuits 33a and 34a and power supply circuits 33b and 34b for the HDD 1a and 1b, respectively. Further, it has power supply control circuits 35a and 35b for the power supply circuits 33a and 34a and the power supply circuits 33b and 34b, respectively. Accordingly, the processor 62 controls the power supply control circuits 35a and 35b independently to control the power supply voltage to be supplied to the HDD 1a and 1b individually. This accomplishes effective and flexible tests for the HDDs 1a and 1b.

In one embodiment, power supply circuits for supplying power supply voltages to the HDDs 1a and 1b are implemented in the adapter cards 3a and 3b corresponding to the respective HDDs. As described above, a number of protocols are present as interfaces for HDDs; the shapes of connectors are different depending on the interface. The operation of the processor 62 can support any specification by changing the test program. Accordingly, the same processor card 6 can be used regardless of the specification of the interface for the HDD. However, it is necessary to change the connectors to be connected to the HDDs 1a and 1b depending on the interface specification for the HDDs 1a and 1b, which can be covered by replacing the adapter cards 3a and 3b.

In this way, the adapter cards 3a and 3b are supposed to be replaced depending on the specification of the HDD 1a and 1b to be connected. Implementing power supply circuits in the adapter cards 3a and 3b leads to preparation of power supply circuits for the specifications and designs of the HDDs 1a and 1b, eliminating the need to replace the processor card 6 or the interface card 4 or eliminating the need to implement power supply circuits supporting all specifications in the processor card 6 or the interface card 4. Implementing power supply circuits in the adapter cards 3a and 3b accomplishes flexible support of HDDs with various specifications and is most effective in decreasing the number of components in the test apparatus. Further, implementing control circuits for the power supply circuits in the adapter cards 3a and 3b accomplishes independent power control in each HDD.

In the above example, the two adapter cards 3a and 3b have the same circuit configuration. The adapter cards are prepared for HDDs of test subjects so that their circuit configurations can be replaced easily for the HDDs to be connected. For example, the capacity of the power supply circuit can be changed depending on the HDD to be connected while generating the same power supply voltage. Besides, implementing different power supply circuits in each adapter card enables HDDs of different operational power supply voltages to be concurrently tested in a test apparatus (chamber).

The above example connects two HDDs 1a and 1b to a single interface controller 43 but an appropriate number may be selected as the number of connection of HDDs depending on the number of ports of the interface controller 43 and processing capacity of the processor 62. Generally, the interface controller 43 is for one specification. Therefore, testing HDDs with different interface specifications using a single processor card 6 can be achieved by connecting a plurality of interface cards 4 to the processor card 6. If the interface controller 43 can perform interface processing of HDDs with different specifications, HDDs with different specifications can be tested by using a single interface card 4.

As set forth above, the test apparatus of certain embodiments comprises power supply circuits for corresponding HDDs on the adapter card so that a processor card can flexibly support tests for HDDs with various power supply specifications with a processor card. Besides, a plurality of HDDs can be tested concurrently with ease using a processor card.

As described above, the adapter card may have a connector to be directly connected to a connector of an HDD, which makes the process to connecting an HDD to the adapter card efficient in a test. However, even if the HDD is connected to the adapter card via a cable, the adapter card of an embodiment with a power supply circuit implemented, is useful.

The test apparatus may comprise a processor card, an interface card, and an adapter card. This is because replacing the interface card allows supporting HDDs with different interfaces without replacing the processor card. However, an interface controller may be implemented in the processor card or the adapter card.

As described above, a plurality of adapter cards may be connected to a single processor card to test a plurality of HDDs concurrently from the view point of the efficiency in the test. However, even if an only HDD is to be tested with connecting a single adapter card to a processor card, the adapter card with a power supply circuit implemented therein, is useful.

As set forth above, the present invention is described by way of a particular embodiments but is not limited to the above embodiments and can of course be modified in various ways within the scope of the substance of embodiments of the present invention. For example, between the adapter card, the interface card, and the processor card, another substrate may be inserted.

What is claimed is:

1. A test apparatus for a data storage device comprising:
a chamber defining space for housing a data storage device of a test subject;
a processor card including a processor for testing the data storage device and a first substrate where the processor is mounted; and
an adapter card including a second substrate located between the processor card and the data storage device for transmitting test signals between the processor card and the data storage device and a power supply circuit mounted on the second substrate for supplying an operational power supply voltage for the data storage device.

2. The test apparatus according to claim 1, wherein:
a connector is fixed to the second substrate of the adapter card; and
the connector is connected directly to a connector of the data storage device.

3. The test apparatus according to claim 1, wherein the adapter card further includes a power supply control circuit for controlling the power supply circuit.

4. The test apparatus according to claim 1, further comprising:
an interface card including a third substrate located between the processor card and the adapter card for transmitting test signals between the processor card and the data storage device and an interface controller mounted on the third substrate for performing interface processes between the processor card and the data storage device.

5. The test apparatus according to claim 1, wherein:
a plurality of adapter cards are connected to the processor card; and
the processor card tests a plurality of data storage devices connected to the plurality of adapter cards concurrently.

6. The test apparatus according to claim 5, further comprising:
an interface card including a fourth substrate located between the processor card and the plurality of adapter cards for transmitting test signals between the processor cards and the plurality of data storage devices and an interface controller mounted on the fourth substrate for performing interface processes between the processor card and the plurality of data storage devices.

7. The test apparatus according to claim 6, wherein the interface card is connected to each of the plurality of adapter cards via a signal transmission cable.

8. The test apparatus according to claim 5, wherein the processor card controls power supply circuits on the plurality of adapter cards individually.

9. A test method for a plurality of data storage devices comprising:
preparing a processor card including a first substrate and a processor mounted on the first substrate;
connecting the plurality of data storage devices to substrates of a plurality of adapter cards for transmitting test signals between the processor card and the plurality of data storage devices;
supplying operational power supply voltages different in each of the plurality of data storage devices by power supply circuits mounted on the adapter cards; and
testing the plurality of data storage devices operating at different operational power voltages by the processor.

10. The method according to claim 9, further comprising performing interface processes of test signals between the processor and the plurality of data storage devices by a single interface controller.

11. The method according to claim 9, wherein each connector of the plurality of data storage devices is connected directly to each connector of the plurality of adapter cards.
